(19) United States
(12) Patent Application Publication
(10) Pub. No.: US 2026/0371928 A1
(43) Pub. Date: Nov. 19, 2026

(54) THERMOELECTRIC CONVERSION ELEMENT AND SENSOR

(71) Applicant: NITTO DENKO CORPORATION, Ibaraki-shi, Osaka (JP)

(72) Inventors: Takumi INOHARA, Ibaraki-shi, Osaka (JP); Yosuke NAKANISHI, Ibaraki-shi, Osaka (JP); Hayato MIZUNO, Ibaraki-shi, Osaka (JP); Takahiro NAKAI, Ibaraki-shi, Osaka (JP)

(21) Appl. No.: 19/470,614

(22) PCT Filed: Mar. 7, 2024
(86) PCT No.: PCT/JP2024/008894

§ 371 Date: Sep. 29, 2025

(30) Foreign Application Priority Data
Mar. 31, 2023 (JP) 2023-057432

(51) Int. Cl. H10N 15/20

(52) U.S. Cl. CPC H10N 15/20

(57) ABSTRACT

A thermoelectric conversion element includes a substrate and a thermoelectric conversion body. The thermoelectric conversion body is disposed on a first surface of the substrate. The thermoelectric conversion body has a second surface intersecting with a perpendicular line to the first surface. At least one selected from the group consisting of the first surface and the second surface has a maximum height roughness Rz of 30 nm or less.

### TECHNICAL FIELD

The present invention relates to a thermoelectric conversion element and a sensor.

### BACKGROUND ART

A conventionally known thermoelectric conversion element has a structure in which a material exhibiting thermoelectric conversion characteristics is disposed on a substrate.

For example, Patent Literature 1 describes a thermoelectric conversion element having a laminate including a substrate, a buffer layer, and two mixture layers. The substrate may be a flexible substrate. The buffer layer is provided on the substrate and has a predetermined crystal structure of AlN. The two mixture layers are provided on the buffer layer. The mixture layers each have an alloy layer and a cap layer from the side closer to the buffer layer. The alloy layer includes a predetermined magnetic material. The magnetic material includes a polycrystalline Co-based Heusler alloy. The Co-based Heusler alloy exhibits a large anomalous Nernst effect. The cap layer includes AlN. This laminate exhibits a large anomalous Nernst effect or anomalous Hall effect due to the alloy layer sandwiched between layers including AlN, thereby achieving high thermoelectric conversion efficiency.

### CITATION LIST

### Patent Literature

Patent Literature 1: JP 2022-129848 A

### SUMMARY OF INVENTION

### Technical Problem

In monitoring of physical condition in the Internet of Things (IOT) society or in thermal management in the technical field such as batteries for electric vehicle (EV) or chips for high-speed data processing, the needs for heat monitoring have been increased. To address the needs, it is considered that a thermoelectric conversion element having a thermoelectric conversion body provided on a substrate is used for thermal sensing. It has been considered as important that such a thermoelectric conversion element has high durability in the usage environment.

For the thermoelectric conversion element described in Patent Literature 1, the durability in the usage environment is not specifically reviewed. The thermoelectric conversion element described in Patent Literature 1 has a laminated structure including a substrate, a buffer layer, and two mixture layers. In a laminated structure, cracks may occur in specific layers depending on the usage environment. For example, if a crack occurs in the alloy layer of the thermoelectric conversion element described in Patent Literature 1, the desired thermoelectric conversion performance may be impaired. Patent Literature 1 fails to address this issue, and the thermoelectric conversion element described in Patent Literature 1 may require further consideration from the viewpoint of durability in the usage environment.

In view of the above circumstances, the present invention provides a thermoelectric conversion element that is advantageous from the viewpoint of durability in the usage environment.

### Solution to Problem

The present invention provides a thermoelectric conversion element including:
a substrate; and
a thermoelectric conversion body disposed on a first surface of the substrate and having a second surface intersecting with a perpendicular line to the first surface, wherein
at least one selected from the group consisting of the first surface and the second surface has a maximum height roughness Rz of 30 nm or less.

The present invention also provides a sensor including the aforementioned thermoelectric conversion element.

### Advantageous Effects of Invention

The aforementioned thermoelectric conversion element is advantageous from the viewpoint of durability in the usage environment.

### BRIEF DESCRIPTION OF DRAWINGS

FIG. 1 is a perspective view showing an example of an embodiment of a thermoelectric conversion element.

FIG. 2 is a cross-sectional view of the thermoelectric conversion element shown in FIG. 1, with a plane II as the cross sectional plane.

FIG. 3 is a graph showing a relation between an external magnetic field and magnetization of a thermoelectric conversion body according to an embodiment.

FIG. 4 is a side view showing an example of a thermoelectric conversion element having a wound structure.

FIG. 5 is a diagram showing an example of an embodiment of sensor.

FIG. 6 is a perspective view showing another example of an embodiment of thermoelectric conversion element.

FIG. 7 is a schematic view showing a method for measuring internal stress in a thermoelectric conversion body.

### DESCRIPTION OF EMBODIMENTS

The following describes embodiments of the present invention with reference to the drawings. The following description is intended to illustrate the present invention, but not to limit the present invention to the embodiments described herein.

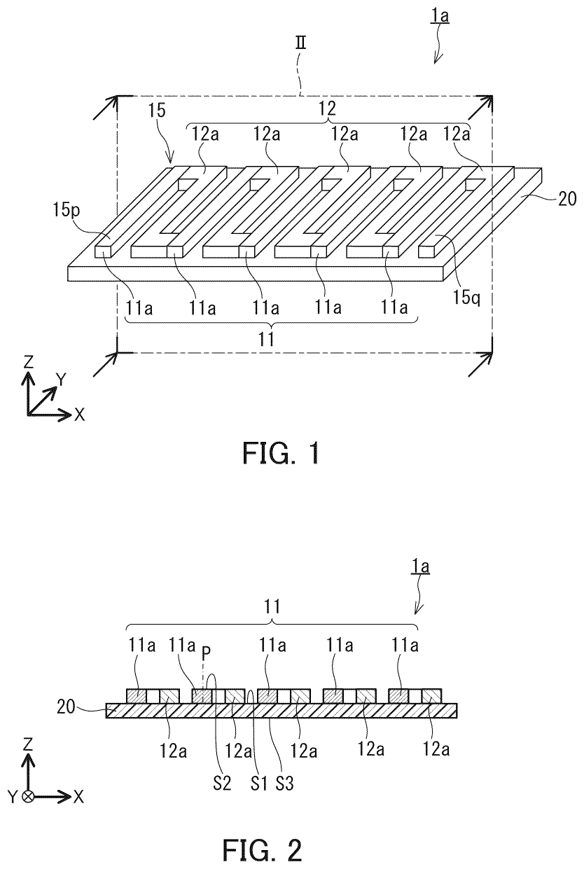

As shown in FIG. 1 and FIG. 2, the thermoelectric conversion element 1a includes a substrate 20 and a thermoelectric conversion body 11. The thermoelectric conversion body 11 is disposed on a first surface S1 of the substrate 20. The thermoelectric conversion body 11 has a second surface S2 intersecting with a perpendicular line P to the first surface S1. In the thermoelectric conversion element 1a, at least one selected from the group consisting of the first surface S1 and the second surface S2 has a maximum height roughness Rz of 30 nm or less. The maximum height roughness Rz is determined, for example, in accordance with Japanese Industrial Standards (JIS) B 0601:2013. The first surface S1 and the second surface S2 are, for example, surfaces parallel to the XY plane. In the attached drawings, the X-axis, Y-axis, and Z-axis are mutually orthogonal, and the Z-axis is perpendicular to the first surface S1.

According to the investigations carried out by the present inventors, in order to improve the thermoelectric conversion performance of a thermoelectric conversion element having a thermoelectric conversion body provided on a substrate, it is advantageous to adjust the internal stress in the thermoelectric conversion body to a predetermined state. On the other hand, it has been newly found that adjustment of the internal stress in the thermoelectric conversion element to a predetermined state may cause cracks in the thermoelectric conversion body due to the internal stress, thereby impairing the thermoelectric conversion performance of the thermoelectric conversion element, depending on the usage environment. It has been found that cracks may occur in the thermoelectric conversion body particularly when the thermoelectric conversion element is exposed to a high temperature and high humidity environment for an extended period of time. It has been found that the occurrence of such cracks is related not only to the state of internal stress in the thermoelectric conversion body but also to the surface condition of the substrate in contact with the thermoelectric conversion body.

In the manufacture of a thermoelectric conversion element including a thermoelectric conversion body provided on a substrate, it is conceivable to form a film of a precursor of the thermoelectric conversion body on the surface of the substrate during conveyance of the substrate. For example, when conveying substrates that are stacked on top of each other, substrates with a surface having irregularities are used to prevent blocking caused by the stacking of the substrates. According to the investigations by the present inventors, it has been found that the irregularities on the surface of the substrate are involved in occurrence of cracks in the thermoelectric conversion body in a case where the thermoelectric conversion element is exposed to a high temperature and high humidity environment for an extended period of time.

After extensive trials and errors, the present inventors have newly discovered that cracks in the thermoelectric conversion body can be reduced by adjusting the maximum height roughness Rz of at least one selected from the group consisting of the surface of the substrate in contact with the thermoelectric conversion body and the surface of the thermoelectric conversion element to a predetermined range.

As described above, at least one selected from the group consisting of the first surface S1 and the second surface S2 has a maximum height roughness Rz of 30 nm or less. Thereby, for example, even when the thermoelectric conversion element is exposed to a high temperature and high humidity environment for an extended period of time, cracks are less likely to occur in the thermoelectric conversion body. Therefore, the thermoelectric conversion element 1a is likely to exhibit high durability in the usage environment. The maximum height roughness Rz may be 25 nm or less, 20 nm or less, or 15 nm or less, and, for example may be 1 nm or more.

As shown in FIG. 2, the substrate 20 has, for example, a third surface S3. The third surface S3 is a surface apart from the thermoelectric conversion body 11 and extending parallel to the first surface S1. The surface state of the third surface S3 is not limited to a specific state. The third surface S3 has, for example, an arithmetic mean roughness Ra of 8 nm or more. With such a configuration, in a case of conveying the substrate 20 during the manufacture of the thermoelectric conversion element 1a, blocking caused by overlapping of the substrates 20 is less likely to occur, making it easier to convey the substrates 20. The arithmetic mean roughness Ra may be determined, for example, in accordance with JIS B 0601:2013.

The arithmetic mean roughness Ra of the third surface S3 may be 9 nm or more, or may be 10 nm or more. The arithmetic mean roughness Ra of the third surface S3 may be, for example, 20 nm or less, 15 nm or less, or may be 12 nm or less. The arithmetic mean roughness Ra of the third surface S3 may fall within any of the ranges defined by all possible combinations of one lower limit selected from 8 nm, 9 nm, and 10 nm, and one upper limit selected from 20 nm, 15 nm, and 12 nm.

The minimum internal stress σₘᵢₙ in the thermoelectric conversion body 11 is not limited to a specific value. The minimum internal stress σₘᵢₙ is the minimum value of the internal stress of the thermoelectric conversion body 11 in the plane parallel to the first surface S1. The minimum internal stress σₘᵢₙ is, for example, −300 MPa or less. In this case, the thermoelectric conversion performance of the thermoelectric conversion element 1a tends to be high. In the present Description, positive internal stress indicates tensile stress, and negative internal stress indicates compressive stress. The fact that the minimum internal stress σₘᵢₙ is −300 MPa or less indicates that relatively large compressive stress exists as internal stress in the thermoelectric conversion body 11. In a case where the thermoelectric conversion element is exposed to a high temperature and high humidity environment for an extended period of time, such compressive stress tends to cause cracks in the thermoelectric conversion body in combination with the surface irregularities of the substrate. However, in a case where the maximum height roughness Rz of one selected from the group consisting of the first surface S1 and the second surface S2 is 30 nm or less, cracks are less likely to occur in the thermoelectric conversion body 11 even if the minimum internal stress σₘᵢₙ is −300 MPa or less. Therefore, the thermoelectric conversion element 1a is likely to exhibit high durability in the usage environment.

The minimum internal stress σₘᵢₙ is, for example, −900 MPa or more. The minimum internal stress σₘᵢₙ may fall within any of the ranges defined by all possible combinations of one upper limit selected from −300 MPa, −350 MPa, −400 MPa, −450 MPa, −500 MPa, −550 MPa, and −600 MPa, and one lower limit selected from −900 MPa, −850 MPa, −800 MPa, −750 MPa, and −700 MPa.

The thermoelectric conversion body 11 is, for example, in the form of a thin wire 11a containing a magnetic material. With such a configuration, for example, the thermoelectric conversion element 1a can easily exhibit the desired thermoelectric conversion performance due to the thermoelectric conversion characteristics of the magnetic material. The thermoelectric conversion body 11 is formed of, for example, a plurality of thin wires 11a.

As shown in FIG. 1, the thin wires 11a extend, for example, along the Y-axis direction. The thickness of the thin wires 11a, namely, the dimension in the Z-axis direction is not limited to a specific value. The thickness is, for example, 1000 nm or less. This can reduce the amount of material to be used for the thin wire 11a, making it easier to reduce the cost for manufacturing the thermoelectric conversion element 1a. In addition, wire breaking in the thermoelectric conversion body 11 is unlikely to occur. The thickness of the thin wire 11a is, for example, 5 nm or more. This allows the thermoelectric conversion element 1a to exhibit high durability.

The thickness of the thin wire 11a may fall within any of the ranges defined by all possible combinations of one lower limit selected from 5 nm, 10 nm, 20 nm, 30 nm, and 50 nm, and one upper limit selected from 1000 nm, 750 nm, 500 nm, 400 nm, 300 nm, and 200 nm.

The width of the thin wire 11a in the X-axis direction is not limited to a specific value. The width of the thin wire 11a is, for example, 500 μm or less. Thereby, the amount of material used for the thin wire 11a can be reduced to easily reduce the cost for manufacturing the thermoelectric conversion element 1a. Further, it facilitates arrangement of numbers of thin wires 11a in the X-axis direction, allowing the thermoelectric conversion element 1a to exhibit easily the desired thermoelectric conversion performance. The width of the thin wire 11a is, for example, 1 μm or more. This makes it less likely for the thin wire 11a to break, thereby enabling the thermoelectric conversion element 1a to have higher durability.

The width of the fine line 11a may fall within any of the ranges defined by all possible combinations of one lower limit selected from 1 μm, 2 μm, 5 μm, 10 μm, 20 μm, and 30 μm, and one upper limit selected from 500 μm, 400 μm, 300 μm, 200 μm, 100 μm, and 50 μm.

The difference between the first internal stress σ_{Y} and the second internal stress σ_{X} of the thermoelectric converter 11, namely, |σ_{X}−σ_{Y}|, is not limited to a specific value. The first internal stress σ_{Y} is the internal stress of the thermoelectric conversion body 11 in the length direction (Y-axis direction) of the thin wire 11a. The second internal stress σ_{X} is the internal stress of the thermoelectric conversion body 11 in the width direction (X-axis direction) of the thin wire 11a. The difference |σ_{X}−σ_{Y}| is, for example, 50 MPa or more. In this case, the magnetic properties of the magnetic material contained in the thin wire 11a are likely to exhibit significant anisotropy in both the length direction and the width direction, making it easier for the thermoelectric conversion body 11 to exhibit the desired thermoelectric conversion characteristics. As a result, the thermoelectric conversion element 1a is more likely to exhibit the desired thermoelectric conversion performance.

As described above, the thin wire 11a extends linearly in the Y-axis direction. Therefore, considering shape magnetic anisotropy, it is conceivable that in the thermoelectric conversion body 11, an easy axis of magnetization is generated in the length direction of the thin wire 11a, and a hard axis of magnetization is generated in the width direction of the thin wire 11a. However, in the thermoelectric conversion body 11, when the difference |σ_{X}−σ_{Y}| is 50 MPa or more, the magnetic properties of the magnetic material included in the thin wire 11a is likely to exhibit significant anisotropy in both the length direction and the width direction. For example, the magnetic anisotropy energy Eᵤ of a magnetic body is related to λ by an equation Eᵤ=(3/2)λσ. In this relation, λ is a magnetostriction constant of the magnetic body, and σ indicates the internal stress of the magnetic body. Therefore, for example, when the difference σ_{X}−σ_{Y} has a larger positive value in a case where the magnetostriction constant λ is positive, or when the difference σ_{X}−σ_{Y} has smaller negative value in a case where the magnetostriction constant λ is negative, the anisotropy of the magnetic properties of the magnetic material in the length direction and in the width direction of the thin wire 11a is greater.

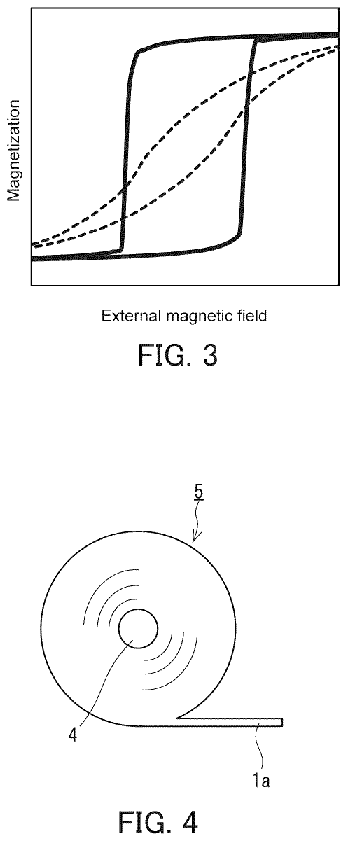

FIG. 3 is a graph showing a relation between an external magnetic field and magnetization of the thermoelectric conversion body 11. In FIG. 3, the solid line shows the relation between the external magnetic field and the magnetization of the thermoelectric conversion body 11 in the width direction (X-axis direction) of the thin wire 11a. The dashed line shows the relation between the external magnetic field and the magnetization of the thermoelectric conversion body 11 in the length direction (Y-axis direction) of the thin wire 11a. As shown in FIG. 3, in the thermoelectric conversion body 11, the magnetic properties of the thermoelectric conversion body 11 exhibit significant anisotropy in both the length direction and the width direction of the thin wire 11a due to the difference |σ_{X}−σ_{Y}| being 50 MPa or more. Due to this significant anisotropy in magnetic properties, the thermoelectric conversion body 11 is likely to exhibit a hard axis of magnetization in the length direction of the thin wire 11a and an easy axis of magnetization in the width direction of the thin wire 11a. Thereby, the thermoelectric conversion body 11 is likely to exhibit stable behavior with respect to an external magnetic field, so that the thermoelectric conversion element 1a is likely to exhibit the desired thermoelectric conversion performance. The magnetic material contained in the thin wire 11a preferably has an easy axis of magnetization in the width direction of the thin wire 11a.

In the thermoelectric conversion body 11, the difference |σ_{X}−σ_{Y}| may be 100 MPa or more, 150 MPa or more, or 200 MPa or more. The upper limit of the difference |σ_{X}−σ_{Y}| is not limited to a specific value. The difference |σ_{X}−σ_{Y}| may be, for example, 900 MPa or less. In this case, even when bending loads are applied to both ends of the thin wire 11a in the width direction, cracks are unlikely to occur in the thermoelectric conversion body 11.

The first internal stress or may be tensile stress or compressive stress. The first internal stress σ_{Y} may fall within any of the ranges defined by all possible combinations of one lower limit selected from −900 MPa, −700 MPa, −500 MPa, and −300 MPa, and one upper limit selected from 900 MPa, 700 MPa, 500 MPa, and 300 MPa.

The second internal stress ox may be tensile stress or compressive stress. The second internal stress σ_{X} may fall within any of the ranges defined by all possible combinations of one lower limit selected from −900 MPa, −700 MPa, −500 MPa, and −300 MPa, and one upper limit selected from 900 MPa, 700 MPa, 500 MPa, or 300 MPa.

The magnetostriction constant of the magnetic material contained in the thin wire 11a may be positive or negative. For example, a requirement σ_{X}−σ_{Y}≥50 MPa may be satisfied in a case where the magnetostriction constant of this magnetic material is positive, and a requirement σ_{Y}−σ_{X}≥50 MPa may be satisfied in a case where the magnetostriction constant of this magnetic material is negative. In the former case, the first internal stress σ_{Y} may be the minimum internal stress σₘᵢₙ, and in the latter case, the second internal stress σ_{X} may be the minimum internal stress σₘᵢₙ.

A squareness ratio determined by an M-H curve in the width direction of the thin wire 11a of the thermoelectric conversion body 11 is not limited to a specific value. The squareness ratio is a ratio Mr/Ms of the remanent magnetization Mr to the saturation magnetization Ms in the M-H curve. The squareness ratio is, for example, 80% or more. This enables the thermoelectric conversion element 1a to exhibit the desired thermoelectric conversion performance more effectively. The squareness ratio may be 85% or more, and may be 90% or more.

The thermoelectric conversion body 11 generates an electromotive force in the length direction (Y-axis direction) of the thin wire 11a due to a temperature gradient VT in the direction perpendicular to the first surface S1 (Z-axis direction). With this configuration, the electromotive force generated by thermoelectric conversion can be adjusted by adjusting the length of the thin wire 11a, so that the thermoelectric conversion element 1a can be used in various applications.

The thermoelectric conversion body 11 generates an electromotive force, for example, by the magneto-thermoelectric effect. The magneto-thermoelectric effect is, for example, the anomalous Nernst effect.

The thermoelectric converters 11 contain, for example, a substance exhibiting the anomalous Nernst effect. The substance exhibiting the anomalous Nernst effect is not limited to a particular substance. The substance exhibiting the anomalous Nernst effect is, for example, a magnetic body having saturation magnetic susceptibility of 5×10⁻³ T or more, or a substance of a band structure with a Weyl point near the Fermi energy. The magnetic body may be a ferrimagnetic body. The thermoelectric conversion body 11 contains, for example, at least one substance selected from the group consisting of (i), (ii), (iii), (iv) and (v) below, as a substance exhibiting the anomalous Nernst effect.
(i) A stoichiometric substance having a composition represented by Fe₃X
(ii) An off-stoichiometric substance having a composition ratio of Fe and X that deviates from that of the substance in (i) above
(iii) A substance in which a part of the Fe site of the substance in (i) above or a part of the Fe site in the substance in (ii) above is substituted by a typical metal element or a transition element other than X
(iv) A substance having a composition represented by Fe₃M1₁₋ₓM2ₓ (0<x<1), where M1 and M2 are typical elements different from each other
(v) A substance in which a part of the Fe site of the substance in (i) above is substituted by a transition element other than X, and a part of the X site in the substance in (i) above is substituted by a typical metal element other than X

In the substances (i) to (v), X is a typical element or a transition element. X is, for example, Al, Ga, Ge, Sn, Si, Ti, Zr, Hf, V, Nb, Ta, Cr, Mo, W, Sc, Ni, Mn, or Co. In the above (iv), the combination of M1 and M2 is not limited to a specific combination as long as M1 and M2 are typical elements different from each other. In the above (iv), the combination of M1 and M2 is, for example, Ga and Al, Si and Al, or Ga and B.

The thermoelectric conversion body 11 may contain Co₂MnGa or Mn₃Sn as a substance exhibiting the anomalous Nernst effect.

The magnetostriction constant λ of the magnetic material contained in the thin wire 11a is not limited to a specific value. The absolute value of the magnetostriction constant λ is, for example, 5×10⁻⁶ or more. As described above, the magnetic anisotropy energy Eᵤ of the magnetic body has the relation Eᵤ=(3/2)λσ. Therefore, when the absolute value of the magnetostriction constant λ is 5×10⁻⁶ or more, the magnetic property anisotropy in the length direction and the width direction of the thin wire 11a tends to increase.

The absolute value of the magnetostriction constant λ may be 10×10⁻⁶ or more, or may be 20×10⁻⁶ or more.

As shown in FIG. 1, the thermoelectric conversion element 1a has a meander pattern including the thermoelectric conversion body 11. With this configuration, the total length of the thin wires 11a included in the thermoelectric conversion element 1a tends to be large. The electromotive force generated in the length direction of the thin wire 11a due to the temperature gradient VT perpendicular to the first surface S1 tends to increase as the total length of the thin wires 11a increases. Therefore, the thermoelectric conversion element 1a tends to generate a larger electromotive force by having a meander pattern including the thermoelectric conversion body 11.

As shown in FIG. 1 and FIG. 2, the thermoelectric conversion element 1a further includes, for example, a wiring 12. The wiring 12 electrically connects the thin wires 11a to each other. For example, a plurality of thin wires 11a in the thermoelectric conversion body 11 are electrically connected in series by the wiring 12. The wiring 12 may, for example, include a plurality of wirings 12a. The thin wires 11a and the wirings 12a are electrically connected in series. With such a configuration, even if the area of the surface on which the thin wires 11a and the wirings 12a are disposed is small, a large electromotive force is easily generated in the thermoelectric conversion element 1a.

The wiring 12 may be formed of a simple metal or an alloy.

The fine wirings 11a and the wirings 12a are disposed, for example, to form the aforementioned meander pattern. Thereby, a conductive path 15 is formed. For example, the electromotive force generated in the thermoelectric conversion element 1a can be extracted to the outside by connecting one end portion 15p and the other end portion 15q of the conductive path 15 to an external wiring. Alternatively, by applying a voltage between the one end portion 15p and the other end portion 15q, a heat flow can be generated in the thickness direction of the substrate 20.

The thin wires 11a are disposed, for example, at predetermined intervals in the X-axis direction and parallel to each other. For example, the thin wires 11a are disposed at equal intervals in the X-axis direction. The wirings 12a electrically connect, for example, the fine wires 11a adjacent to each other in the X-axis direction. The wirings 12a each electrically connect, for example, one end part in the Y-axis direction of each thin wire 11a and the other end part in the Y-axis direction of another thin wire 11a adjacent to the first-described thin wire 11a. One end part in the Y-axis direction of each of the thin wires 11a is located at the end part of the same side in the Y-axis direction of the thin wires 11a, and the other end part in the Y-axis direction of each the thin wires 11a is located at the end part opposite to the one end part in the Y-axis direction of the thin wires 11a.

The thickness, which is the dimension of the wiring 12a in the Z-axis direction, is not limited to a specific value. The thickness may fall within any of the ranges defined by all possible combinations of one lower limit selected from 5 nm, 10 nm, 20 nm, 30 nm, and 50 nm, and one upper limit selected from 1000 nm, 750 nm, 500 nm, 400 nm, 300 nm, and 200 nm.

The width of the wiring 12a is not limited to a specific value. The width may fall within any of the ranges defined by all possible combinations of one lower limit selected from 0.1 μm, 0.5 μm, 1 μm, 2 μm, 5 μm, 10 μm, 20 μm, and 30 μm, and one upper limit selected from 500 μm, 400 μm, 300 μm, 200 μm, 100 μm, and 50 μm.

The substrate 20 is not limited to a specific substrate, as long as at least one of the group consisting of the first surface S1 and the second surface S2 has a maximum height roughness Rz of 30 nm or less.

The substrate 20 may contain, for example, organic materials. With such a configuration, internal stress in the thermoelectric conversion body 11 can be easily adjusted to a state desired from the viewpoint of thermoelectric conversion performance. Additionally, the cost for manufacturing the thermoelectric conversion element 1a can be reduced.

The substrate 20 includes, for example, an organic material such as an organic polymer. Examples of the organic polymers include polyethylene terephthalate (PET), polyethylene naphthalate (PEN), acrylic resin (PMMA), polycarbonate (PC), polyimide (PI), and cycloolefin polymer (COP).

The thickness of the substrate 20 is not limited to a specific value. Its thickness is, for example, 10 μm to 250 μm.

The substrate 20 is, for example, flexible. The substrate 20 has elasticity such that, when a test piece made from the substrate 20 is wound around a cylindrical mandrel with a diameter of 10 cm so that both ends of the test piece in the length direction of the test piece face the same direction, the test piece can be elastically deformed.

The difference |C_{X}−C_{Y}| between the second dimensional change rate C_{X} and the first dimensional change rate C_{Y} of the substrate 20 is not limited to a specific value. The first dimensional change rate C_{Y} is the value obtained, in a test where the substrate 20 is heated at 150 °C for 30 minutes, by dividing the dimension at 25 °C in the length direction (Y-axis direction) of the thin wire 11a along the first surface S1 after the test by the dimension at 25 °C before the test. The second dimensional change rate C_{X} is the value obtained by dividing the dimension at 25 °C in the width direction (X-axis direction) of the thin wire 11a after the test by the dimension at 25 °C before the test. The difference |C_{X}−C_{Y}| is, for example, 0.10% or more. In this case, for example, by performing a predetermined heat treatment in the state where the precursor of the thermoelectric conversion body 11 is formed on the first surface S1 of the substrate 20, the degree of shrinkage of the substrate 20 after the heat treatment differs in the length direction and width direction of the thin wire 11a. This makes it easier to adjust the internal stress in the thermoelectric conversion body 11 to a desired state from the viewpoint of thermoelectric conversion performance.

The difference |C_{X}−C_{Y}| may be 0.2% or more, 0.3% or more, 0.4% or more, or 0.5% or more, and is, for example, 10% or less.

The first surface S1 of the substrate 20 may be formed with a surface layer such as a hard coat layer.

An example of a method for manufacturing a thermoelectric conversion element 1a is described below. The thermoelectric conversion element 1a is manufactured by a method including, for example, the following (I) and (II).
(I) Forming a precursor of the thermoelectric conversion body 11 on the first surface S1 of the substrate 20.
(II) Heat-treating the substrate 20 and the precursor of the thermoelectric conversion body 11 at a predetermined temperature.

In (I), for example, a film of the precursor of the thermoelectric conversion body 11 is formed on the first surface S1 of the substrate 20 by any of methods such as sputtering, chemical vapor deposition (CVD), pulsed laser deposition (PLD), ion plating, and plating. Next, for example, a photoresist is applied onto the film, a photomask is placed on the film, and exposure is performed, followed by wet etching. Thereby, thin wires of the precursor of the thermoelectric conversion body 11 are formed, the wires are disposed at predetermined intervals. Next, a precursor film for the wiring 12 is formed onto the first surface S1 of the substrate 20, using any of methods such as sputtering, CVD, PLD, ion plating, and plating. Next, a photoresist is applied onto the precursor film for the wiring 12, a photomask is placed on the precursor film for the wiring 12, and exposure is performed, followed by wet etching. Thereby, the wiring 12 is obtained, and the thin wires of the precursor of the thermoelectric conversion body 11 are electrically connected to each other.

The temperature during the heating treatment in (II) is not limited to a specific temperature. The ambient temperature of the substrate 20 and the precursor of the thermoelectric conversion body 11 during the heating treatment is, for example, 50 °C or higher. This makes it easier to adjust the internal stress of the thermoelectric conversion body 11 to a state desired from the viewpoint of thermoelectric conversion performance. The temperature of the substrate 20 and the precursor of the thermoelectric conversion body 11 during the heating process may be 100 °C or higher, 150 °C or higher, or 200 °C or higher. The temperature is, for example, 300 °C or lower.

The time period during which the ambient temperature of the substrate 20 is maintained at 50 °C or higher in the heating treatment is not limited to a specific time. The time is, for example, 10 minutes or longer and 3 hours or shorter.

After the heating treatment, the precursor of the thermoelectric conversion body 11 is magnetized, whereby the thermoelectric conversion body 11 is obtained. For example, the thermoelectric conversion element 1a is manufactured in this manner.

The thermoelectric conversion element 1a can be provided, for example, together with a pressure-sensitive adhesive layer. In this case, the substrate 20 is disposed between the thermoelectric conversion body 11 and the pressure-sensitive adhesive layer in the thickness direction of the substrate 20. Thereby, it is possible to attach the thermoelectric conversion element 1a to an article by pressing the pressure-sensitive adhesive layer onto the article.

The pressure-sensitive adhesive layer includes, for example, a rubber-based pressure-sensitive adhesive, an acrylic pressure-sensitive adhesive, a silicone-based pressure-sensitive adhesive, or a urethane-based pressure-sensitive adhesive. The thermoelectric conversion element 1a may be provided together with a pressure-sensitive adhesive layer and a release liner. In this case, the release liner covers the pressure-sensitive adhesive layer. Typically, the release liner is a film that can maintain the adhesiveness of the pressure-sensitive adhesive layer while covering the layer, and it can be peeled off easily from the pressure-sensitive adhesive layer. The release liner is, for example, a film made of a polyester resin like PET. By peeling off the release liner, the pressure-sensitive adhesive layer is exposed and the thermoelectric conversion element 1a can be adhered to an article.

As shown in FIG. 4, the thermoelectric conversion element 1a may be provided as a wound structure 5. For example, a film-like or sheet-like thermoelectric conversion element 1a is wound around the side face of a cylindrical or columnar core 4 to form the wound structure 5.

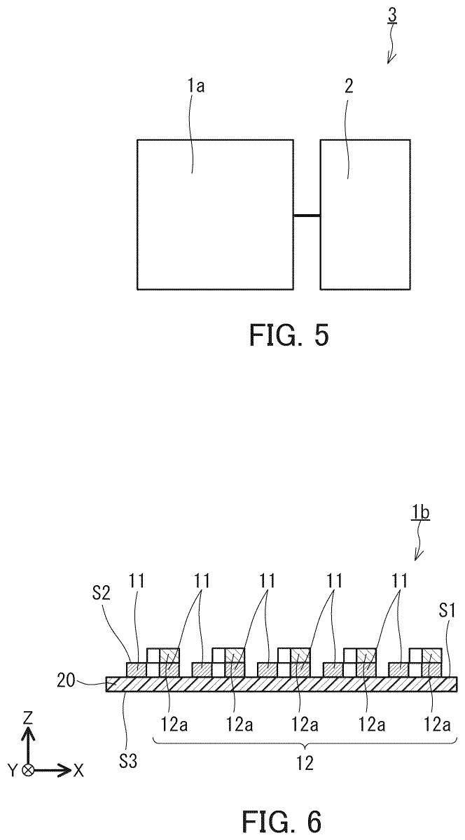

As shown in FIG. 5, for example, a sensor 3 including a thermoelectric conversion element 1a may be provided. In this sensor 3, for example, when a temperature gradient VT occurs in the thickness direction of the substrate 20, an electromotive force is generated in the length direction of the thin wire 11a. The sensor 3 is capable of sensing heat by processing electrical signals output to the outside of the thermoelectric conversion element 1a, where the electrical signals are based on the electromotive force. The sensor 3 further includes a signal processing device 2. In the signal processing device 2, the electrical signal output from the thermoelectric conversion element 1a is processed.

The thermoelectric conversion element 1a can be modified from various viewpoints. For example, the thermoelectric conversion element 1a may be modified to a thermoelectric conversion element 1b shown in FIG. 6. The thermoelectric conversion element 1b is configured similarly to the thermoelectric conversion element 1a, except for the parts described in detail. Components of the thermoelectric conversion element 1b, which are the same as or correspond to the components of the thermoelectric conversion element 1a, are denoted by the same reference numerals, and detailed descriptions therefor are omitted. The description of the thermoelectric conversion element 1a applies to the thermoelectric conversion element 1b unless technically contradictory.

As shown in FIG. 6, in the thermoelectric conversion element 1b, a thermoelectric conversion body 11 extends continuously on a first surface S1, for example. The wiring 12 is disposed on a part of the thermoelectric conversion body 11. For example, the wirings 12a included in the wiring 12 are disposed on the thermoelectric conversion body 11 at predetermined intervals from each other.

In the thermoelectric conversion element 1b, the thermoelectric conversion body 11 is, for example, formed in a meander pattern. The thermoelectric conversion element 1b is configured such that, in a plan view, a single layer of the thermoelectric conversion body 11 and a laminated structure including the thermoelectric conversion body 11 and the wiring 12a alternate in the X-axis direction.

### EXAMPLES

The present invention will now be described in more detail with reference to Example, though the present invention is not limited to the Example.

### Example 1

A thin film having a thickness of 96 nm was formed by DC magnetron sputtering using a target material containing Fe and Ga, on a hard coat layer having a thickness of 4 μm as a surface layer for a polyethylene terephthalate (PET) film having a total thickness of 54 μm. In the DC magnetron sputtering process, argon gas was supplied as the process gas at a pressure of 0.1 Pa. In the target material, a relation of Fe content: Ga content is 3:1 at the atomic ratio was satisfied. The ambient temperature of the PET film A was adjusted to 100 °C. The PET film A with the formed thin film was heated in an environment of 150 °C for 30 minutes. Subsequently, a photoresist was applied onto the thin film, a photomask was placed over the thin film, and exposure was performed, followed by wet etching. The thus formed 115 FeGa-containing thin wires were disposed at predetermined intervals. The width of each FeGa-containing thin wire was 40 μm, and the length of each FeGa-containing thin wire was 1.5 cm. Subsequently, using a target material containing Cu, a Cu thin film having a thickness of 100 nm was formed on the hard coat layer of the PET film A by DC magnetron sputtering. Photoresist was applied onto the Cu thin film, a photomask was placed on the Cu thin film, and exposure was performed, followed by wet etching. Thereby, Cu-containing thin wires having a width of 40 μm were formed. The Cu-containing thin wires electrically connected adjacent pairs of FeGa-containing linear patterns, forming a meander pattern of conductive path.

Using an electromagnet having a center magnetic flux density of 0.5 T, the FeGa-containing thin wires were magnetized in the width direction, the width direction being parallel to the main surface of the PET film A and perpendicular to the length direction of the FeGa-containing thin wires. In this way, the thermoelectric conversion element according to Example 1 was manufactured. In this thermoelectric conversion element, the perpendicular direction (TD) of the PET film A was aligned with the width direction of the FeGa-containing thin wires.

### Comparative Example 1

A thermoelectric conversion element according to Comparative Example 1 was prepared in the same manner as in Example 1, except that the PET film A was replaced by a PET film B having a total thickness of 50 μm and having no hard coat layer.

### Comparative Example 2

A thermoelectric conversion element according to Comparative Example 1 was prepared in the same manner as in Example 1, except for the following points. That is, the PET film A was replaced by the PET film B used in Comparative Example 1. And the pressure of the argon gas supplied as the process gas in the DC magnetron sputtering was adjusted to 1.6 Pa.

### Comparative Example 3

A thermoelectric conversion element according to Comparative Example 3 was prepared in the same manner as Example 1, except for using a PET film C different from the PET films used in Example 1 and Comparative Example 1.

### [Magnetic Properties]

Using a portable cryogen-free physical property measurement system PPMS-versalab supplied by Quantum Design Inc., the magnetic properties of the FeGa-containing thin wires of the thermoelectric conversion element in Example and each Comparative Example were measured. For this measurement, a measurement sample, which was prepared by cutting a module disposed with a conductive path according to Example and each Comparative Example into 2 mm square pieces, was used. Further in the measurement, by using Vibration Sample Magnetrometer (VSM), a magnetic field of +800 [kA/m] was swept in a direction parallel to the magnetization direction of the magnetized FeGa-containing thin wires, thereby obtaining a M-H curve by considering the thickness of the FeGa-containing thin wires and the area occupied by the FeGa-containing thin wires in the measurement sample, under a condition of temperature of 300 K. A ratio Mr/Ms of the magnetization value Ms at ±800 [kA/m] and the magnetization value Mr at ±0 [kA/m] was determined as a squareness ratio. The results are shown in Table 1.

### [Measurement of Internal Stress]

Using an X-ray diffractometer (Smartlab) manufactured by Rigaku Corporation, Cu-Kα rays were irradiated onto the sample through a parallel beam optical system from a light source of 40 kV and 50 mA, whereby the first internal stress oy and second internal stress σ_{X} of the FeGa-containing thin wires in Example and each Comparative Example were measured using the sin²Ψ method of the inclination measurement principle. The first internal stress σ_{Y} was the internal stress in the length direction of the FeGa-containing thin wires, and the second internal stress σ_{X} was the internal stress in the width direction parallel to the main plane of the PET film and perpendicular to the length direction of the FeGa-containing thin wires. The wavelength λ of the Cu-Kα rays was 0.1541 nm. The sin²Ψ method is a technique for determining the internal stress of a thin film, based on the dependence of the crystal lattice distortion angle (Ψ) of a polycrystalline thin film. Using the above-described X-ray diffractometer, Θ/2Θ scan measurement was performed to measure the diffraction intensity at intervals of 0.01° in the range of 2θ=75° to 85°. The integration time at each measurement point was set to 100 seconds. From the peak angle 20 of the obtained X-ray diffraction and the wavelength λ of the X-rays emitted from the light source, the crystal interplanar spacing d of the magnetic body at each measurement angle (Ψ) was calculated. The crystal lattice distortion & was calculated from the interplanar spacing d according to the relation of the following Equations (1) and (2). λ is the wavelength of the X-rays (Cu-Kα rays) emitted from the light source, and λ=0.1541 nm. d₀ is the interplanar spacing of the crystal in the stress-free state, and d₀=0.0206 nm.

2d sin θ=λ Equation (1)

ε=(d−d₀)/d₀ Equation (2)

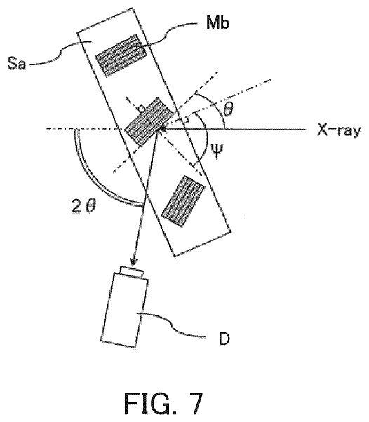

As shown in FIG. 7, X-ray diffraction measurements were performed for each case where the angle (Ψ) between the normal to the main surface of sample Sa and the normal to the crystal plane of crystal Mb was 0°, 17°, 24°, 30°, 35°, 40°, and 45°, and the crystal lattice distortion & was calculated for each angle (Ψ). Subsequently, the first internal stress σ_{Y} and the second internal stress σ_{X} were determined from the slope of the straight line plotting the relation between the sin²Ψ and the crystal lattice distortion ε, according to the following Equation (3). The results are shown in Table 1. As to the internal stress in Table 1, the positive values indicates tensile stress, while the negative value indicates compressive stress. In the side inclination method, stress is measured in a direction of 90° to the beam direction. Therefore, in determining the first internal stress oY and the second internal stress σ_{X}, the sample was placed such that the measurement direction was perpendicular to the beam direction, and measurements were performed. The results are shown in Table 1.

ε={(1+v)/E}σ sin²Ψ−(2v/E)σ Equation (3)

In the above Equation (3), E is the Young's modulus of the magnetic body (130 GPa), and v is the Poisson's ratio (0.3) of the magnetic body. The detector D in FIG. 7 detects X-ray diffraction.

### [Measurement of Surface Roughness]

Using a 3D non-contact surface roughness measurement meter NewView 7300 manufactured by Zygo Corporation, the surfaces of each PET film where FeGa-containing thin wires were formed and the surfaces of the FeGa thin wires were measured under conditions of an objective lens having 10 magnifications and a measurement area of 0.70 mm×0.52 mm, and roughness curves for each surface were obtained. From the obtained roughness curves, the arithmetic mean roughness R and the maximum height roughness Rz were calculated in accordance with JIS B0601:2013. The results are shown in Table 1.

### [Dimensional Change Rate of Substrate]

A heating test was performed by heating test pieces prepared from the substrates used in Example and each Comparative Example at 150 °C for 30 minutes. The first dimensional change rate C_{Y} was determined as the value obtained by dividing the dimensions in the length direction of the FeGa-containing thin wires at 25 °C after the heating test by the dimensions at 25 °C before the heating test. The second dimensional change rate C_{X} was determined as the value obtained by dividing the dimension in the width direction of the FeGa-containing thin wires s at 25 °C after the heating test by the dimensions at 25 °C before the heating test. In addition, the difference |C_{X}−C_{Y}| between the second dimensional change rate C_{X} and the first dimensional change rate C_{Y} was calculated. The results are shown in Table 1.

### [High Temperature and High Humidity Environmental Test]

The environment for the thermoelectric conversion element in Example and each Comparative Example was maintained for 120 hours under conditions of temperature of 85 °C and a relative humidity of 85% so as to perform a high temperature and high humidity environmental test. The measurement targets were: an electrical resistance R₀ of the conductive path before the high temperature and high humidity environmental test; an electrical resistance R₂₄ of the conductive path 24 hours after the start of the high temperature and high humidity environmental test; and an electrical resistance R₁₂₀ of the conductive path after the high temperature and high humidity environmental test. It was determined that the conductive path was broken when the electrical resistance R₂₄ or the electrical resistance R₁₂₀ was 1.5 times or more than the electrical resistance R₀. The results are shown in Table 1.

As shown in Table 1, in Example 1, no breaking in the conductive path was observed even after 120 hours of the high temperature and high humidity environmental test. On the other hand, in each Comparative Example, breaking in the conductive path was observed after 120 hours of the high temperature and high humidity environmental test. A comparison between Example 1 and each Comparative Example suggested that high durability can be maintained over a long period of time in a high temperature and high humidity environmental test when the maximum height roughness Rz of the surface of the PET film where the FeGa-containing thin wires are formed or the surface of the FeGa thin wires is 30 nm or less.

It can be understood from a comparison between Example 1 and Comparative Example 2 that a larger difference |σ_{X}−σ_{Y}| is likely to increase the squareness ratio, making the FeGa-containing thin wires more likely to have magnetic properties desired from the viewpoint of thermoelectric conversion performance.

In Comparative Example 1, no breaking in the conductive path was observed 24 hours after the start of the high temperature and high humidity environmental test. On the other hand, in Comparative Example 2, breaking in the conductive path was observed 24 hours after the start of the high temperature and high humidity environmental test. In Comparative Example 2, internal stress as relatively large tensile stress was generated in the FeGa-containing thin wires, and tensile stress generated due to the expansion of the PET film accompanying exposal to the high temperature and high humidity environment further contributed to occurrence of cracks in the FeGa-containing thin wires. On the other hand, in Comparative Example 1, internal stress as compressive stress was generated in the FeGa-containing thin wires, and the FeGa-containing thin wires were able to withstand the tensile stress generated due to the expansion of the PET film accompanying exposal to a high temperature and high humidity environment, and no cracks occurred in the FeGa-containing thin wires. On the other hand, when the PET film was exposed to a high temperature and high humidity environment for 120 hours, an area around the interface between the FeGa-containing thin wires and the PET film deteriorated, reducing their adhesion. This is considered to have led to buckling in the FeGa-containing thin wires due to compressive stress, resulting in cracks in the FeGa-containing thin wires. The propagation direction of the cracks that occurred in the FeGa-containing thin wires in the high temperature and high humidity environmental test of Comparative Example 1 differed from the propagation direction of cracks that occurred in the FeGa-containing thin wires in the high temperature and high humidity environmental test of Comparative Example 2. As described above, this suggests that the crack occurrence mechanisms in Comparative Examples 1 and 2 were different from each other.

In Comparative Example 3, breaking in the conductive path was observed 24 hours after the start of the high temperature and high humidity environmental test. Comparison between Example 1 and Comparative Example 3 indicates that, in order to exhibit high durability over a long period of time in a high temperature and high humidity environmental test, it is desirable that the difference |C_{X}−C_{Y}| in the PET film as the substrate be 0.1% or more.

TABLE 1

| | | | Comparative | Comparative | Comparative |
|---|---|---|---|---|---|
| | | Example 1 | Example 1 | Example 2 | Example 3 |
| Substrate | | PET film A | PET film B | PET film B | PET film C |
| Maximum height roughness Rz [nm] of | | 11 | 114 | 114 | 61 |
| FeGa-containing thin wire | | | | | |
| Maximum height roughness Rz [nm] of | | 10 | 116 | 116 | 63 |
| substrate surface on which FeGa- | | | | | |
| containing thin wire is formed | | | | | |
| Arithmetic mean roughness Ra [nm] of | | 6 | 13 | 13 | 12 |
| substrate surface on which FeGa- | | | | | |
| containing thin wire is formed | | | | | |
| Arithmetic mean roughness Ra [nm] of | | 10 | 14 | 14 | 12 |
| substrate surface apart from surface on | | | | | |
| which FeGa-containing thin wire is | | | | | |
| formed | | | | | |
| First internal stress σ_{Y} [MPa] | | −660 | −658 | 905 | — |
| Second internal stress σ_{X} [MPa] | | −390 | −402 | 910 | — |
| \|σ_{X}-σ_{Y}\| [MPa] | | 270 | 256 | 5 | — |
| First dimensional change rate C_{Y} (TD) [%] | | 0.17 | 0.15 | — | 0.48 |
| Second dimensional change rate C_{X} (MD) | | −0.30 | −0.29 | — | 0.45 |
| [%] | | | | | |
| \|C_{X}-C_{Y}\| [%] | | 0.47 | 0.44 | — | 0.03 |
| Squareness ratio Mr/Ms [%] | | 90 | 90 | 77 | 83 |
| High | 24 hours | Not broken | Not broken | Broken | Not broken |
| temperature and | | | | | |
| high humidity | 120 hours | Not broken | Broken | Broken | Broken |
| test | | | | | |

A first aspect of the present disclosure provides a thermoelectric element including:
a substrate; and
a thermoelectric conversion body disposed on a first surface of the substrate and having a second surface intersecting with a perpendicular line to the first surface, wherein
at least one selected from the group consisting of the first surface and the second surface has a maximum height roughness Rz of 30 nm or less.

A second aspect of the present disclosure provides a thermoelectric conversion element according to the first aspect, wherein
the substrate has a third surface apart from the first surface and extending parallel to the first surface, and
the third surface has an arithmetic mean roughness Ra of 8 nm or more.

A third aspect of the present disclosure provides a thermoelectric conversion element according to the first or the second aspect, wherein
the thermoelectric conversion body has a minimum internal stress of −300 MPa or less, and
the minimum internal stress is a minimum value of internal stress of the thermoelectric conversion body in a plane parallel to the first surface.

A fourth aspect of the present disclosure provides a thermoelectric conversion element according to any one of the first to the third aspects, wherein
the thermoelectric conversion body is in the form of a thin wire including a magnetic material.

A fifth aspect of the present disclosure provides a thermoelectric conversion element according to the fourth aspect, wherein
a difference between a first internal stress of the thermoelectric conversion body in a length direction of the thin wire and a second internal stress of the thermoelectric conversion body in a width direction perpendicular to the length direction and parallel to the first surface is 50 MPa or more.

A sixth aspect of the present disclosure provides a thermoelectric conversion element according to the fourth or the fifth aspect, wherein
the thermoelectric conversion body generates an electromotive force in the length direction of the thin wire by a temperature gradient in a direction perpendicular to the first surface.

A seventh aspect of the present disclosure provides a thermoelectric conversion element according to any one of the first to the sixth aspects, wherein the substrate includes an organic material.

An eighth aspect of the present disclosure provides a thermoelectric conversion element according to any one of the first to the seventh aspects, wherein
the thermoelectric conversion element has a meander pattern including the thermoelectric conversion body.

A ninth aspect of the present disclosure provides a thermoelectric conversion element according to any one of the first to the eighth aspects, wherein
the thermoelectric conversion element has a wound structure.

A tenth aspect of the present disclosure provides a sensor that includes a thermoelectric conversion element according to any one of the first to the ninth aspects.

1. A thermoelectric conversion element comprising:
a substrate; and
a thermoelectric conversion body disposed on a first surface of the substrate and having a second surface intersecting with a perpendicular line to the first surface, wherein
at least one selected from the group consisting of the first surface and the second surface has a maximum height roughness Rz of 30 nm or less.

2. The thermoelectric conversion element according to claim 1, wherein
the substrate has a third surface apart from the first surface and extending parallel to the first surface, and
the third surface has an arithmetic mean roughness Ra of 8 nm or more.

3. The thermoelectric conversion element according to claim 1, wherein
the thermoelectric conversion body has a minimum internal stress of −300 MPa or less, and
the minimum internal stress is a minimum value of internal stress of the thermoelectric conversion body in a plane parallel to the first surface.

4. The thermoelectric conversion element according to claim 1, wherein
the thermoelectric conversion body is in the form of a thin wire including a magnetic material.

5. The thermoelectric conversion element according to claim 4, wherein
a difference between a first internal stress of the thermoelectric conversion body in a length direction of the thin wire and a second internal stress of the thermoelectric conversion body in a width direction perpendicular to the length direction and parallel to the first surface is 50 MPa or more.

6. The thermoelectric conversion element according to claim 4, wherein
the thermoelectric conversion body generates an electromotive force in the length direction of the thin wire by a temperature gradient in a direction perpendicular to the first surface.

7. The thermoelectric conversion element according to claim 1, wherein
the substrate comprises an organic material.

8. The thermoelectric conversion element according to claim 1, wherein
the thermoelectric conversion element has a meander pattern including the thermoelectric conversion body.

9. The thermoelectric conversion element according to claim 1, wherein
the thermoelectric conversion element has a wound structure.

10. A sensor comprising the thermoelectric conversion element according to claim 1.
